(19) United States
(12) Patent Application Publication
(10) Pub. No.: US 2025/0081343 A1
(43) Pub. Date: Mar. 6, 2025

(54) PRINTED CIRCUIT BOARD

(71) Applicant: SAMSUNG ELECTRO-MECHANICS CO., LTD., Suwon-si (KR)

(72) Inventors: Chi Hyeon JEONG, Suwon-si (KR); Seok Hwan KIM, Suwon-si (KR); Dong Hyeon LEE, Suwon-si (KR); Hyun Sang KWAK, Suwon-si (KR)

(73) Assignee: SAMSUNG ELECTRO-MECHANICS CO., LTD., Suwon-si (KR)

(21) Appl. No.: 18/435,155

(22) Filed: Feb. 7, 2024

(30) Foreign Application Priority Data
Sep. 4, 2023 (KR) 10-2023-0116899

(51) Int. Cl. H05K 1/11

(52) U.S. Cl. CPC H05K 1/115; H05K 2201/09563; H05K 2201/10234

(57) ABSTRACT

The present disclosure relates to a printed circuit board including: an insulating layer, a through-hole penetrating the insulating layer from an upper surface to a lower surface of the insulating layer and having an inclined wall surface; a metal ball disposed within the through-hole and in contact with the inclined wall surface; and a metal via filling the through-hole and surrounding the metal ball.

### CROSS-REFERENCE TO RELATED APPLICATION(S)

This application claims benefit of priority to Korean Patent Application No. 10-2023-0116899 filed on Sep. 4, 2023, in the Korean Intellectual Property Office, the disclosure of which is incorporated herein by reference in its entirety.

### TECHNICAL FIELD

The present disclosure relates to a printed circuit board.

Package technology continues to develop, and specifically, attempts to use silicon or glass to break away from the use of organic materials in traditional substrate manufacturing methods continue. Here, glass is known to have better warpage properties and planarization than conventional organic materials, which may be advantageous for reducing a line and a space of traces. However, in the manufacturing of a current substrate, it may be difficult to form a through-via in a thick glass core thereof. For example, a seed layer may be required to proceed with plating in a via hole, but because a glass surface is smooth and the via hole has a high aspect ratio, it may be difficult to form a seed. In addition, when forming a seed using a sputtering process and the like, it may take a significant amount of time and costs to form a seed having a desired thickness.

### SUMMARY

An aspect of the present disclosure is to provide a printed circuit board that may improve the quality of a substrate by suppressing the formation of voids or seams even when fill plating is performed on a through-hole having a high aspect ratio, such as a through-hole formed in a glass core.

Another aspect of the present disclosure is to provide a printed circuit board that may minimize time and costs by minimizing a sputtering process even when a seed is formed in a through-hole having a high aspect ratio, such as a through-hole formed in a glass core.

One of the various solutions proposed through the present disclosure is to form a through-hole having an inclined wall in an insulating layer of as a glass core, insert and seat a metal ball inside the through-hole, and then form a seed layer in the through-hole by a sputtering process, and also is to perform fill plating to form a metal via surrounding a metal ball.

According to an aspect of the present disclosure, a printed circuit board may include: an insulating layer; a through-hole penetrating between an upper surface and a lower surface of the insulating layer and having an inclined wall surface; a metal ball disposed within the through-hole and in contact with the inclined wall surface; and a metal via filling the through-hole and surrounding the metal ball.

According to another aspect of the present disclosure, a printed circuit board may include: an insulating layer having a through-hole; a metal ball disposed within the through-hole; a first seed metal layer disposed on an upper surface of the insulating layer, and extending from an upper region of the through-hole to a wall surface of the through-hole to cover a portion of the metal ball; a second seed metal layer disposed on a lower surface of the insulating layer, and extending from a lower region of the through-hole to the wall surface of the through-hole to cover another portion of the metal ball; a first metal layer disposed on the first seed metal layer and filling a portion of the through-hole in the upper region of the through-hole; and a second metal layer disposed on the second seed metal layer and filling another portion of the through-hole in the lower region of the through-hole.

One effect of the present disclosure is to provide a printed circuit board that may improve the quality of a substrate by suppressing the formation of voids or seams even when fill plating is performed on a through-hole having a high aspect ratio, such as a through-hole formed in a glass core.

Another effect of the present disclosure is to provide a printed circuit board that may minimize time and costs by minimizing a sputtering process even when a seed is formed in a through-hole having a high aspect ratio, such as a through-hole formed in a glass core.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIGS. 4A to 4F are process cross-sectional views schematically illustrating an example of manufacturing the printed circuit board of FIG. 3;

FIG. 5 is a cross-sectional view schematically illustrating another example of a printed circuit board;

FIGS. 6A to 6F are process cross-sectional views schematically illustrating an example of manufacturing the printed circuit board of FIG. 5; and

FIGS. 7A to 7C are cross-sectional views schematically illustrating various examples of metal balls.

### DETAILED DESCRIPTION

Hereinafter, the present disclosure will be described with reference to the accompanying drawings. In the drawings, the shape and size of the elements may be exaggerated or reduced for clearer description.

### Electronic Device

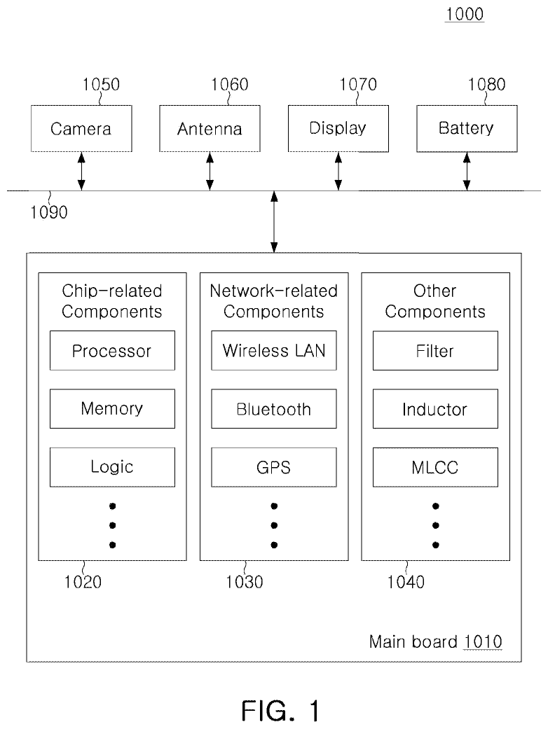

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may be in the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. Furthermore, these other electronic components may also other electronic components used for various purposes depending on a type of electronic device 1000.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

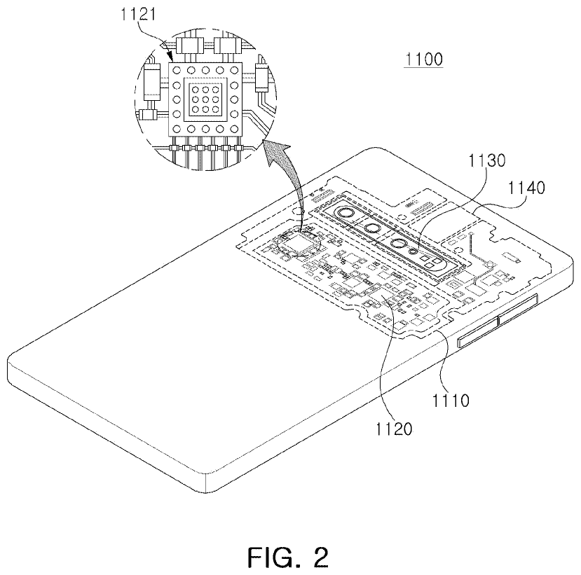

FIG. 2 is a perspective view schematically illustrating an example of an electronic device.

Referring to FIG. 2, an electronic device may be, for example, a smartphone 1100. A motherboard 1110 may be accommodated in the smartphone 1100, and various components 1120 may be physically and/or electrically connected to the motherboard 1110. Furthermore, other components that may or may not be physically and/or electrically connected to the motherboard 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may be in the form of a printed circuit board in which an electronic component including an active component and/or a passive component is mounted on a surface. Alternatively, the component package 1121 may be in the form of a printed circuit board in which an active component and/or a passive component are embedded. On the other hand, the electronic device is not necessarily limited to the smartphone 1100, and may be other electronic devices as described above.

### Printed Circuit Board

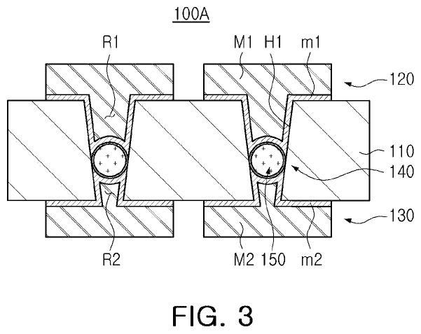

FIG. 3 is a cross-sectional view schematically illustrating an example of a printed circuit board.

Referring to FIG. 3, a printed circuit board 100A according to an example embodiment may include an insulating layer 110, a through-hole H1 penetrating through the insulating layer 110 from an upper surface to a lower surface of the insulating layer 110 and having an inclined wall surface, a metal ball 150 disposed in the through-hole H1, a metal via 140 filling the through-hole H1 and surrounding the metal ball 150, a first metal wiring 120 disposed on the upper surface of the insulating layer 110 and connected to an upper end of the metal via 140, and a second metal wiring 130 disposed on the lower surface of the insulating layer 110 and connected to a lower end of the metal via 140. The through-hole H1 may be tapered so that a width of an upper end thereof is wider than a width of a lower end thereof on a cross-section. The metal ball 150 may be seated in the through-hole H1 by the inclined wall surface of the through-hole H1. A diameter of the metal ball may be bigger than a smallest width of the through-hole so that the metal ball is fitted inside the through-hole. The through-hole H1 may have an upper region R1 and a lower region R2 divided by the metal ball 150. The through-hole H1 may have a tapered shape, and thus, since the metal ball 150 is disposed in an appropriate position, areas of the upper region R1 and the lower region R2 may be different from each other on the cross-section.

Meanwhile, the metal via 140 may include a first seed metal layer ml disposed on an inclined wall surface in the upper region R1 and covering an upper exposed portion of the metal ball 150, a second seed metal layer m2 disposed on an inclined wall surface in the lower region R2 and covering a lower exposed portion of the metal ball 150, a first metal layer M1 disposed on the first seed metal layer ml in the upper region R1 to fill a portion of the through-hole H1, and a second metal layer M2 disposed on the second seed metal layer m2 in the lower region R2 to fill another portion of the through-hole H1. The metal via may include the first metal wiring 120 and the second metal wiring 130. Furthermore, the first metal wiring 120 may include a first seed metal layer m1 disposed on an upper surface of the insulating layer 110 and a first metal layer M1 disposed on the first seed metal layer m1, and the second metal wiring 130 may include a second seed metal layer m2 disposed on a lower surface of the insulating layer 110 and a second metal layer M2 disposed on the second seed metal layer m2. The metal ball 150 may preferably include a copper ball, and in this regard, each of the first and second seed metal layers m1 and m2 and the first and second metal layers M1 and M2 may preferably include copper Cu.

Meanwhile, the insulating layer 110 may include a glass layer. The glass layer may include glass that is an amorphous solid. Glass may include, for example, pure silicon dioxide (about 100% SiO₂), soda lime glass, borosilicate glass, and aluminosilicate glass. However, the glass is not limited thereto, and alternative glass materials, such as fluorine glass, phosphoric acid glass, chalcogen glass, and the like, may also be used as materials. Additives may also be included to form glass having specific physical properties. These additives may include at least one selected from the group consisting of magnesium, calcium, manganese, aluminum, lead, boron, iron, chromium, potassium, sulfur, antimony, calcium carbonate (e.g., lime), sodium carbonate (e.g., soda), and combination thereof. The glass layer may be a layer distinct from organic insulating materials including glass fibers (glass fiber, glass cloth, and glass fabric), copper clad laminate (CCL), prepreg (PPG), and the like. For example, the glass layer may be a plate glass.

As described above, in the printed circuit board 100A according to some example embodiments, in a case of forming a metal via 140 having a high aspect ratio in an insulating layer 110 having a considerable thickness, such as a glass layer, the metal ball 150 may be inserted in advance into the through-hole H1, and then fitted in the through-hole H1 and contacting the inclined wall surface of the through-hole H1, followed by a plating process. For example, after inserting the metal ball 150, the first and second seed metal layers m1 and m2 may be formed in both directions using sputtering, which may easily form seeds and minimize the sputtering process. Accordingly, the metal ball 150 may be fixed so as not to be detached. Furthermore, after inserting the metal ball 150, the first and second metal layers M1 and M2 may be formed in both directions using fill plating, which may effectively suppress an occurrence of voids or seams in the through-hole H1. Thus, the quality of the substrate may be improved.

Meanwhile, the printed circuit board 100A according to some example embodiments may be applied as any one layer of a multilayer circuit board. For example, a core layer of a multilayer circuit board may be applied, and in this case, a build-up process may be performed on one side or both sides of the printed circuit board 100A. The multilayer circuit board may be used as Film-Chip Board (FCB), Ball Grid Array (BGA), an interposer substrate, and a package substrate. However, the present disclosure is not limited thereto, and the multilayer circuit board may be applied to other various types of substrates.

Hereinafter, components of the printed circuit board 100A according to an example embodiment will be described in more detail with reference to the drawings.

The insulating layer 110 may include an insulating material. The insulating material may include glass, but the present disclosure is not limited thereto, and the insulating material may include various other materials such as ceramic, silicon, and organic insulating materials. The insulating material may include, preferably, glass, and thus the insulating layer 110 may be plate glass, but is not limited thereto.

Each of the first and second metal wirings 120 and 130 may include a metallic material. The metallic material may include at least one selected from the group consisting of copper (Cu), aluminum (Al), silver (Ag), tin (Sn), gold (Au), nickel (Ni), lead (Pb), titanium (Ti), and/or alloys thereof. For example, each of the first and second seed metal layers m1 and m2 and the first and second metal layers M1 and M2 of the first and second metal wirings 120 and 130 may include the above-described metallic material, and may include, preferably, copper (Cu), but the present disclosure is not limited thereto. Each of the first and second metal wirings 120 and 130 may perform various functions according to its design. For example, the first and second metal wirings 120 and 130 may include a signal pattern, a power pattern, or a ground pattern. Each of these patterns may have various shapes such as a line, a plane, and a pad. Each of the first and second metal wirings 120 and 130 may include an electroless plating layer (or chemical copper) and an electrolytic plating layer (or electric copper). Instead of an electroless plating layer (or chemical copper), a sputtering layer may be included therein, and if necessary, both the electroless plating layer (or chemical copper) and the sputtering layer may be included therein.

The metal via 140 may include a metallic material. The metallic material may include at least one selected from the group consisting of copper (Cu), aluminum (Al), silver (Ag), tin (Sn), gold (Au), nickel (Ni), lead (Pb), titanium (Ti), and alloys thereof. For example, each of the first and second seed metal layers m1 and m2 and the first and second metal layers M1 and M2 of the metal via 140 may include the above-described metallic material, and may include, preferably, copper (Cu), but the present disclosure is not limited thereto. The metal via 140 may perform various functions according to its design. For example, the metal via 140 may include a ground via, a power via, and a signal via. The metal via 140 may include an electroless plating layer (or chemical copper) and an electrolytic plating layer (or electric copper). Instead of the electroless plating layer, a sputtering layer may be formed, and if necessary, both the electroless plating layer (or chemical copper) and the sputtering layer may be included therein.

The metal ball 150 may include a metallic material. The metallic material may include at least one selected from the group consisting of copper (Cu), aluminum (Al), silver (Ag), tin (Sn), gold (Au), nickel (Ni), lead (Pb), titanium (Ti), and alloys thereof. For example, the metal ball 150 may include a copper ball, but is not limited thereto. The metal ball 150 may further include a nickel (Ni) layer and/or a solder layer formed on a surface of the copper ball, as described below.

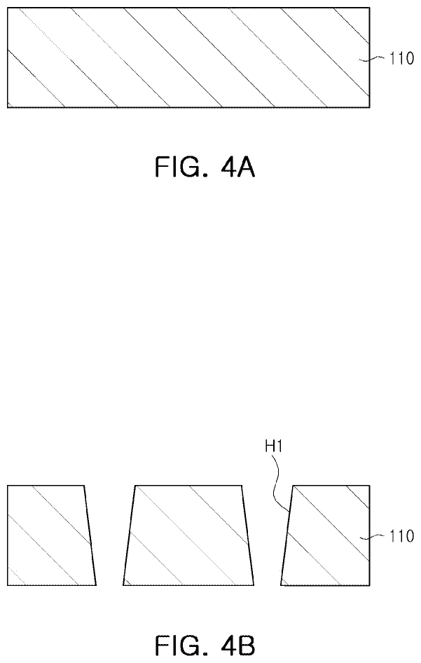

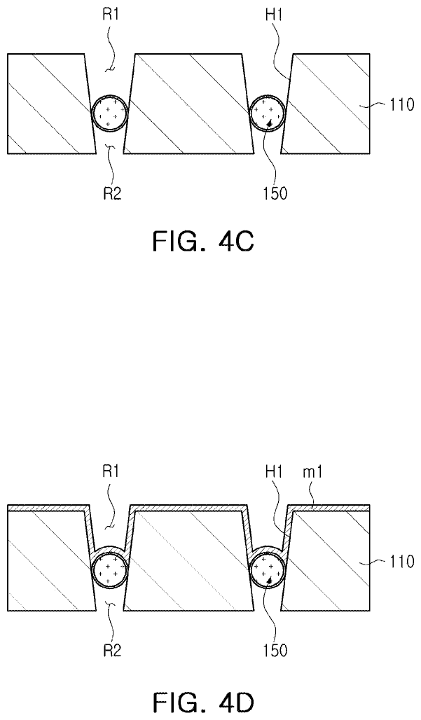

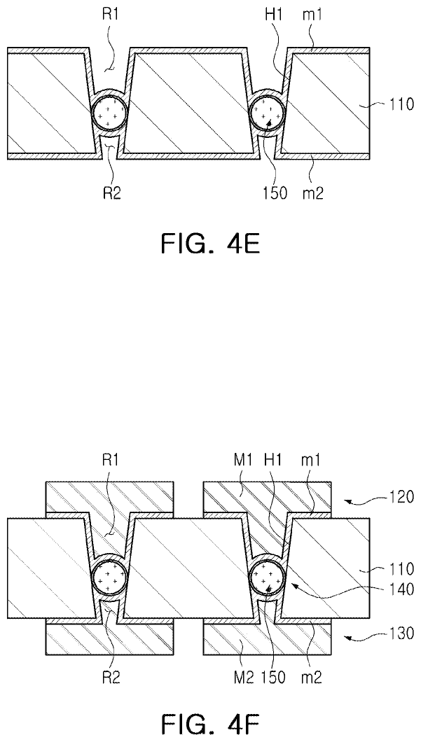

FIGS. 4A to 4F are process cross-sectional views schematically illustrating an example of manufacturing the printed circuit board of FIG. 3.

Referring to the drawings, in FIG. 4A, an insulating layer 110 is prepared. As described above, the insulating layer 110 may be a glass layer such as plate glass. Next, in FIG. 4B, a through-hole H1 is formed in the insulating layer 110. The through-hole H1 may be formed to be tapered by etching after disposing a mask on an upper surface of the insulating layer 110, such as the glass layer, but the present disclosure is not limited thereto. For example, other chemical methods or mechanical methods may be used to form the through-hole H1. A plurality of through-holes H1 may be formed, and each through-hole H1 may be the same or different. Next, in FIG. 4C, the metal ball 150 is inserted into the through-hole H1. The metal ball 150 may be seated in the through-hole H1 and in contact with an inclined wall surface of the tapered through-hole H1. Next, in FIG. 4D, a first seed metal layer m1 is formed on an upper surface of the insulating layer 110 and an upper region R1 of the through-hole H1. The first seed metal layer m1 may be formed by a sputtering process, but the present disclosure is not limited thereto. Next, in FIG. 4E, a second seed metal layer m2 is formed on a lower surface of the insulating layer 110 and a lower region R2 of the through-hole H1. The second seed metal layer m2 may be formed by the sputtering process, but the present disclosure is not limited thereto. Next, in FIG. 4F, first and second metal layers M1 and M2 are formed on the upper surface and the lower surface of the insulating layer 110 and the upper and lower regions R1 and R1 of the through-hole H1. Each of the first and second metal layers M1 and M2 may pattern a dry film resist to form an opening for plating, and then may be formed by fill plating or the like based on the first and second seed metal layers m1 and m2, but the present disclosure not limited thereto. Thereafter, when unnecessary portions of the first and second seed metal layers m1 and m2 are removed by seed etching or the like, the first and second metal wirings 120 and 130 and the metal via 140 may be formed. The printed circuit board 100A according to the above-described example embodiment may be formed through a series of processes, and other contents are substantially the same as described above, and thus overlapping description thereof will be omitted.

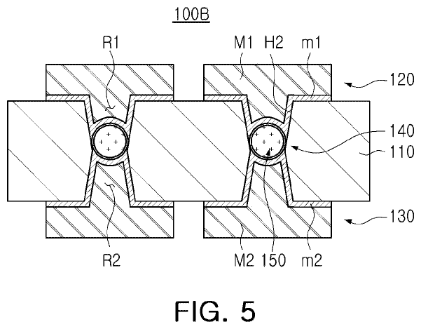

FIG. 5 is a cross-sectional view schematically illustrating another example of a printed circuit board.

Referring to FIG. 5, a printed circuit board 100B according to some other example embodiments may be configured such that in the printed circuit board 100A according to the above-described example embodiment, the through-hole H2 may be tapered to both upper and lower sides of the insulating layer so that a width of each of an upper portion and a lower portion thereof is wider than a width of a certain interior of the through-hole H2 between the upper portion and the lower portion thereof on a cross-section. For example, the through-hole H2 may have an hourglass shape. The metal ball 150 may be inserted into and seated on an upper side of the through-hole H2, but the present disclosure is not limited thereto, and the metal ball 150 may be inserted into and seated on a lower side thereof. Other details are substantially the same as described above, and thus overlapping descriptions thereof are omitted.

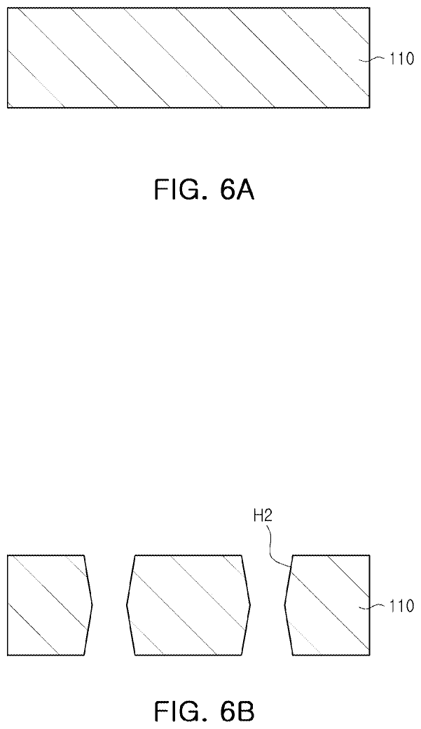

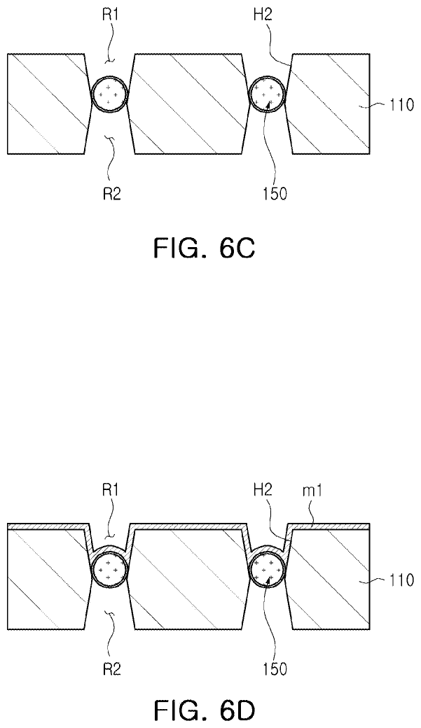

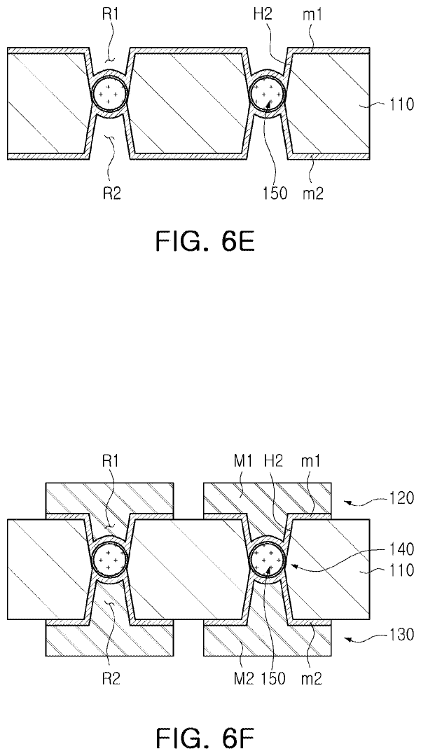

FIGS. 6A to 6F are process cross-sectional views schematically illustrating an example of manufacturing the printed circuit board of FIG. 5.

Referring to the drawings, a printed circuit board 100B according to another example embodiment described above may be formed by substantially the same process as FIGS. 4A to 4F, except that a shape of the through-hole H2 is differently formed. For example, the through-hole H2 may include a tapered first hole formed by first etching after disposing a first mask on an upper surface of an insulating layer 110, such as a glass layer, and also include a tapered second hole formed by second etching after disposing a second mask on a lower surface of the glass layer, so that the through-hole H2 may be formed to be tapered on both sides. However, the present invention is not limited thereto, and the through-hole H2 may be formed by, for example, other chemical methods or mechanical methods.

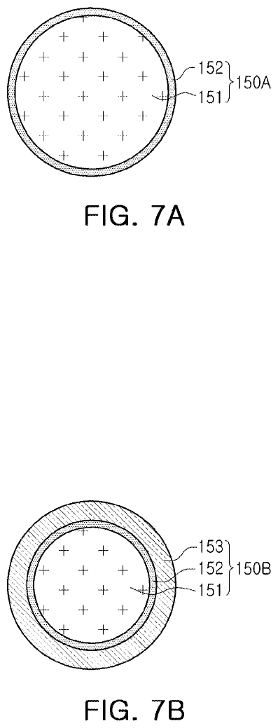

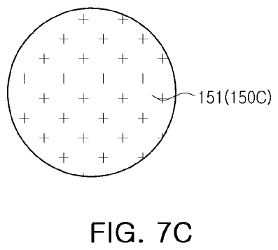

FIGS. 7A to 7C are cross-sectional views schematically illustrating various examples of metal balls.

Referring to the drawings, as illustrated in FIG. 7A, a metal ball 150A may include a nickel (Ni) plating layer 152 formed on a surface of a substantially circular copper ball 151. Alternatively, as illustrated in FIG. 7B, the metal ball 150B may include a nickel (Ni) plating layer 152 formed on a surface of a substantially circular copper ball 151, and a solder plating layer 153 having a thickness greater than the nickel (Ni) plating layer 152 is further formed on a surface of the nickel (Ni) plating layer 152. Alternatively, as illustrated in FIG. 7C, a metal ball 150C may have only the copper ball 151. In this case, the metal balls 150A, 150B and 150C may have various forms, and may be applied as metal balls 150 to the printed circuit board 100A according to the above-described example embodiment or the printed circuit board 100B according to another example embodiment.

In the present disclosure, the expression “covering” may include a case of covering at least a portion as well as a case of covering the whole, and may also include a case of covering not only directly but also indirectly. Furthermore, the expression “filling” may include not only a case of completely filling but also a case of approximately filling, and may include, for example, a case in which some pores or voids exist. In addition, the expression “surrounding” may include not only the case of completely surrounding, but also the case of approximately surrounding.

In the present disclosure, the meaning of the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, a thickness, a width, a length, and a depth may be measured by a scanning microscope or an optical microscope based on a cross-section obtained by polishing or cutting a printed circuit board, respectively. The cut cross-section may be a vertical cross-section or a horizontal cross-section, and each numerical value may be measured based on a required cut cross-section. When the value is not constant, the value may be determined as an average value of values measured at any five points. A width of the upper end and/or the lower end of the through-hole may be measured on a cross-section in which a central axis of the through-hole in a substrate is cut in a thickness direction. A depth of the through-hole may be measured by a distance from an upper end to a lower end of each object on a cross-section in which a central axis of each object in the substrate is cut in the thickness direction.

In the present disclosure, a lower side, a lower portion, and a lower surface are used to refer to a downward direction with respect to a cross-section of a drawing, and an upper side, an upper portion, and an upper surface are used to refer to an opposite direction thereof. However, this defines the direction for convenience of explanation, and the scope of the present disclosure is not particularly limited by the description of such a direction, and the concept of upper and lower portions may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

The expression “example embodiment used in the present disclosure” does not mean the same embodiment, and is provided to explain different unique characteristics. However, the example embodiments presented above do not preclude being implemented in combination with features of other example embodiments. For example, even if matters described in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board comprising:
an insulating layer;
a through-hole penetrating through the insulating layer from an upper surface to a lower surface of the insulating layer and having an inclined wall surface;
a metal ball disposed within the through-hole and in contact with the inclined wall surface; and
a metal via filling the through-hole and surrounding on a surface of the metal ball.

2. The printed circuit board according to claim 1, wherein the through-hole is divided into an upper region and a lower region by the metal ball, and
a cross-section area of the upper region and a cross-section area of the lower region are different.

3. The printed circuit board according to claim 2, wherein the metal via comprises:
a first seed metal layer disposed on the inclined wall surface in the upper region and also cover an upper portion of the metal ball;
a second seed metal layer disposed on the inclined wall surface in the lower region and also cover a lower portion of the metal ball;
a first metal layer disposed on the first seed metal layer to fill an exposed portion of the through-hole in the upper region; and
a second metal layer disposed on the second seed metal layer to fill another portion of the through-hole in the lower region.

4. The printed circuit board according to claim 3, further comprising:
first and second metal wirings disposed on the upper surface and the lower surface of the insulating layer, respectively, and connected to each other through the metal via.

5. The printed circuit board according to claim 4, wherein the metal via comprises the first metal wiring and the second metal wiring,
the first metal wiring comprises the first seed metal layer disposed on the upper surface of the insulating layer, and the first metal layer disposed on the first seed metal layer, and
the second metal wiring comprises the second seed metal layer disposed on the lower surface of the insulating layer, and the second metal layer disposed on the second seed metal layer.

6. The printed circuit board according to claim 5, wherein each of the first and second seed metal layers includes copper, and
each of the first and second metal layers includes copper.

7. The printed circuit board according to claim 1, wherein the through-hole has a tapered shape so that a width of an upper end of the through-hole is wider than a width of a lower end of the through-hole on a cross-section.

8. The printed circuit board according to claim 1, wherein the through-hole has a shape so that a width of each of an upper end and a lower end of the through-hole is wider than a width of a section between the upper end and the lower end thereof on a cross-section.

9. The printed circuit board according to claim 1, wherein the insulating layer includes a glass layer.

10. The printed circuit board according to claim 1, wherein the metal ball includes a copper ball.

11. The printed circuit board according to claim 10, wherein the metal ball further comprises a nickel layer covering a surface of the copper ball.

12. The printed circuit board according to claim 11, wherein the metal ball further includes a solder layer covering a surface of the nickel layer.

13. A printed circuit board comprising:
an insulating layer having a through-hole;
a metal ball disposed within the through-hole;
a first seed metal layer disposed on an upper surface of the insulating layer, an inner wall surface of the through-hole connected to the upper surface of the insulating layer, and an upper portion of the metal ball;
a second seed metal layer disposed on a lower surface of the insulating layer, an inner wall surface of the through-hole connected to the lower surface of the insulating layer, and an lower portion of the metal ball;
a first metal layer disposed on the first seed metal layer and filling a portion of the through-hole in an upper region of the through-hole; and
a second metal layer disposed on the second seed metal layer and filling another portion of the through-hole in a lower region of the through-hole.

14. The printed circuit board according to claim 13, wherein at least a portion of the wall surface of the through-hole has an inclined shape, and
the metal ball is in contact with an inclined portion of the wall surface of the through-hole.

15. The printed circuit board according to claim 13,
wherein the insulating layer includes a glass layer,
the metal ball includes copper balls,
each of the first and second seed metal layers includes copper, and
each of the first and second metal layers includes copper.
